(19) United States
(12) Patent Application Publication
(10) Pub. No.: US 2025/0298055 A1
(43) Pub. Date: Sep. 25, 2025

(54) SEMICONDUCTOR WAFER TESTING APPARATUS

(71) Applicant: Kioxia Corporation, Tokyo (JP)

(72) Inventors: Gaku TAKEMURA, Yokohama (JP); Tomohiko ITO, Kawasaki (JP); Arata INOUE, Chigasaki (JP); Eiji KUME, Odawara (JP)

(73) Assignee: Kioxia Corporation, Tokyo (JP)

(21) Appl. No.: 18/973,235

(22) Filed: Dec. 9, 2024

(30) Foreign Application Priority Data
Mar. 19, 2024 (JP) 2024-044187

(51) Int. Cl. G01R 1/073

(52) U.S. Cl. CPC G01R 1/07342

(57) ABSTRACT

A semiconductor wafer testing apparatus includes a stage configured to place a semiconductor wafer having a plurality of first coils, a probe card configured to hold a plurality of chip inductors having a plurality of second coils, a driver configured to move the probe card toward the stage, and a control circuit including a plurality of transmitting circuits or a plurality of receiving circuits connected to each of the plurality of chip inductors. The control circuit is configured to transmit signals to the plurality of first coils by magnetically coupling the plurality of first coils to each of the plurality of second coils.

### CROSS-REFERENCE TO RELATED APPLICATION(S)

This application is based upon and claims the benefit of priority from the prior Japanese Patent Application No. 2024-044187, filed on Mar. 19, 2024, the entire contents of which are incorporated herein by reference.

### FIELD

An embodiment of the present disclosure relates to a semiconductor wafer testing apparatus.

### BACKGROUND

A semiconductor device exists including an inductor for contactless wireless communication using magnetic coupling. In such a semiconductor device, a communication device can communicate without contact, which reduces the failure rate and the probability of malfunction. In addition, since it is only necessary to bring the communication devices close to each other, access accuracy can be improved and the time can be shortened.

### BRIEF DESCRIPTION OF THE DRAWINGS

FIG. 1 is a cross-sectional view showing a structure of a semiconductor wafer testing apparatus according to an embodiment of the present disclosure.

FIG. 2 is a perspective view showing a structure of a probe card according to an embodiment of the present disclosure.

FIG. 3 is a perspective view showing a structure of a chip inductor according to an embodiment of the present disclosure.

FIG. 4 is a top view showing a structure of a semiconductor wafer according to an embodiment of the present disclosure.

FIG. 5 is a cross-sectional view showing a structure of a semiconductor device according to an embodiment of the present disclosure.

FIG. 6 is a perspective view showing a structure of an inductor according to an embodiment of the present disclosure.

FIG. 7 is a block diagram showing a configuration of a semiconductor device according to an embodiment of the present disclosure.

FIG. 8 is a perspective view showing a configuration of a semiconductor wafer testing apparatus and a semiconductor device and contactless wireless communication according to an embodiment of the present disclosure.

FIG. 9 is a perspective view showing a configuration of a semiconductor wafer testing apparatus and a semiconductor device and contactless wireless communication according to an embodiment of the present disclosure.

FIG. 10 is a perspective view showing a configuration of a semiconductor wafer testing apparatus and a semiconductor device and contactless wireless communication according to an embodiment of the present disclosure.

FIG. 11 is a perspective view showing a configuration of a semiconductor wafer testing apparatus and a semiconductor device and contactless wireless communication according to an embodiment of the present disclosure.

FIG. 12 is a perspective view showing a configuration of a semiconductor wafer testing apparatus and a semiconductor device and contactless wireless communication according to an embodiment of the present disclosure.

FIG. 13 is a perspective view showing a configuration of a semiconductor wafer testing apparatus and a semiconductor device and contactless wireless communication according to an embodiment of the present disclosure.

FIG. 14 is a perspective view showing a configuration of a semiconductor wafer testing apparatus and a semiconductor device and contactless wireless communication according to an embodiment of the present disclosure.

FIG. 15 is a perspective view showing a configuration of a semiconductor wafer testing apparatus and a semiconductor device and contactless wireless communication according to an embodiment of the present disclosure.

FIG. 16 is a perspective view showing a configuration of a semiconductor wafer testing apparatus and a semiconductor device and contactless wireless communication according to an embodiment of the present disclosure.

FIG. 17 is a flowchart showing a process of manufacturing a semiconductor device according to an embodiment of the present disclosure.

### DESCRIPTION OF EMBODIMENTS

Hereinafter, a semiconductor wafer testing apparatus according to an embodiment of the present invention will be described in detail with reference to the drawings. In the following description, elements having substantially the same functions and configurations are denoted by the same reference signs or the same reference signs, followed by letters of the alphabet, and will be described redundantly only when necessary. Each of the embodiments described below exemplifies an apparatus and a method for embodying a technical idea of the present embodiment. Various modifications may be made to the embodiments without departing from the spirit of the invention. These embodiments and modifications thereof are included in the scope of the invention described in the claims and equivalents thereof.

In the drawings, the widths, thicknesses, shapes, and the like of the respective portions may be schematically represented in comparison with the actual embodiments for clarity of explanation, but the drawings are merely examples, and do not limit the interpretation of the present invention. In the present specification and the drawings, elements having the same functions as those described with respect to the above-described drawings are denoted by the same reference signs, and redundant descriptions thereof may be omitted.

In the present specification, the expression “α includes A, B, or C” does not exclude the case where α includes a plurality of combinations of A to C unless otherwise specified. Furthermore, these expressions do not exclude the case where α includes other elements.

The following embodiments can be combined with each other as long as there is no technical contradiction.

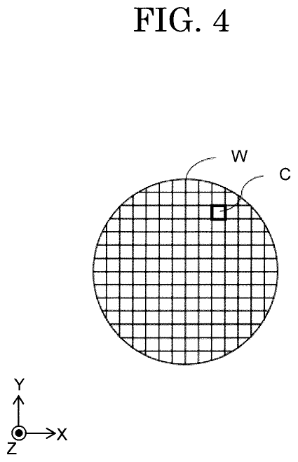

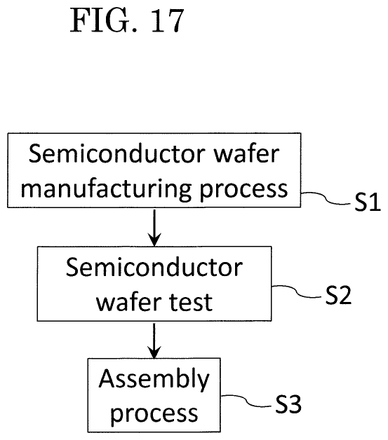

FIG. 17 is a flowchart showing a process of manufacturing a semiconductor device according to the present embodiment. The process of manufacturing a semiconductor device C is roughly divided into two processes: a manufacturing process S1 of a semiconductor wafer W and an assembly process S3. In the manufacturing process S1 of the semiconductor wafer W, elements constituting the semiconductor device C and wirings are formed on the semiconductor wafer W. In the assembly process S3, the semiconductor device C is cut out from the semiconductor wafer W (dicing, see FIG. 4) and sealed in an enclosure (semiconductor package) to produce a final semiconductor product.

After the manufacturing process S1 of the semiconductor wafer W, a test S2 of the semiconductor device C is performed to ensure that each semiconductor device C has been manufactured correctly. The semiconductor wafer testing apparatus of the present embodiment is an apparatus for testing the semiconductor wafer W. In the test S2 of the semiconductor wafer W, a signal current is applied to an inductor i of the semiconductor device C, and a signal current or the like obtained thereby is measured to determine the quality of each semiconductor device C.

A semiconductor wafer testing apparatus according to an embodiment includes a stage configured to place a semiconductor wafer having a plurality of first coils, a probe card configured to hold a plurality of chip inductors having a plurality of second coils, a driver configured to move the probe card toward the stage, and a control circuit including a plurality of transmitting circuits or a plurality of receiving circuits connected to each of the plurality of chip inductors. The control circuit is configured to transmit signals to the plurality of first coils by magnetically coupling the plurality of first coils to each of the plurality of second coils.

### First Embodiment

### Structure of Semiconductor Wafer Testing Apparatus

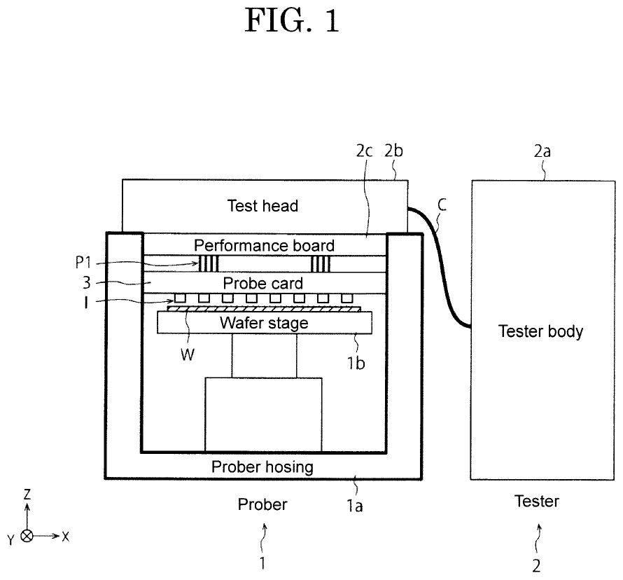

FIG. 1 is a cross-sectional view showing a structure of a semiconductor wafer testing apparatus according to the present embodiment.

The semiconductor wafer testing apparatus of the present embodiment includes a prober 1, a tester 2, and a probe card 3. The prober 1 includes a prober housing 1a and a wafer stage 1b. The tester 2 includes a tester body 2a, a test head 2b, and a performance board 2c.

FIG. 1 shows the X, Y, and Z directions perpendicular to each other. In the present specification, +Z direction is treated as an upward direction, and −Z direction is treated as a downward direction. The −Z direction may coincide with the gravitational direction or may not coincide with the gravitational direction.

The prober 1 holds the semiconductor wafer W to be tested and various parts for the test. Specifically, the prober housing 1a holds the test head 2b, the performance board 2c, and the probe card 3. The test head 2b, the performance board 2c, and the probe card 3 are placed on the prober housing 1a and supported by the prober housing 1a.

On the other hand, the wafer stage 1b holds the semiconductor wafer W. The semiconductor wafer W is placed on the wafer stage 1b and supported by the wafer stage 1b. However, the present embodiment is not limited to this configuration and the prober housing 1a and the wafer stage 1b are merely examples of a housing and stage, respectively. For example, the wafer stage 1b may include a temperature control unit for controlling a temperature of the semiconductor wafer W mounted on the wafer stage 1b.

The prober 1 includes a driver capable of moving the probe card 3 supported by the prober housing 1a in the up-down direction (±Z direction). However, the present invention is not limited to this, and the prober 1 may include a driver capable of moving the semiconductor wafer W supported by the wafer stage 1b in the up-down direction (±Z direction).

The tester 2 tests the semiconductor wafer W held by the prober 1. Specifically, for example, the tester body 2a generates a test signal for testing the semiconductor wafer W, and outputs the test signal to the test head 2b via a cable C. The test head 2b receives the test signal from the tester body 2a via the cable C and outputs the test signal to the performance board 2c. The performance board 2c receives the test signal from the test head 2b and outputs the test signal to the probe card 3. In FIG. 1, the performance board 2c is removably mounted to the test head 2b.

The performance board 2c is electrically connected to the probe card 3 by a plurality of pins P1. The test signal output from the test head 2b is input to the probe card 3 via these pins P1. For example, these pins P1 are pogo pins. These pins P1 may be held by the performance board 2c, by the probe card 3, or by the prober housing 1a.

### Structure of Probe Card

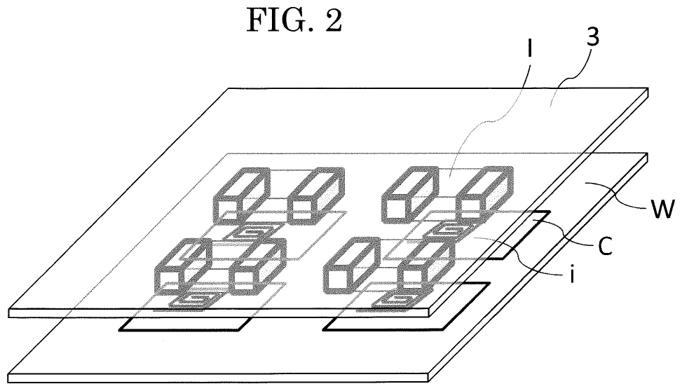

FIG. 2 is a perspective view showing a structure of a probe card of a semiconductor wafer testing apparatus according to the present embodiment.

The probe card 3 is a jig for electrically connecting the performance board 2c to the semiconductor wafer W. The semiconductor wafer W includes a plurality of inductors i. The probe card 3 includes a plurality of chip inductors I. One chip inductor I of the present embodiment is arranged per inductor i. The plurality of chip inductors I is spaced apart from each other. These chip inductors I are held by the probe card 3. The probe card 3 can be electrically connected to the inductor i of the semiconductor device C by the chip inductor I. The probe card 3 includes a signal generating circuit for generating a signal current to be input to the semiconductor wafer W. The signal current output from the probe card 3 is input to the semiconductor device C of the semiconductor wafer W by contactless wireless communication via these chip inductors I.

### Structure of Chip Inductor

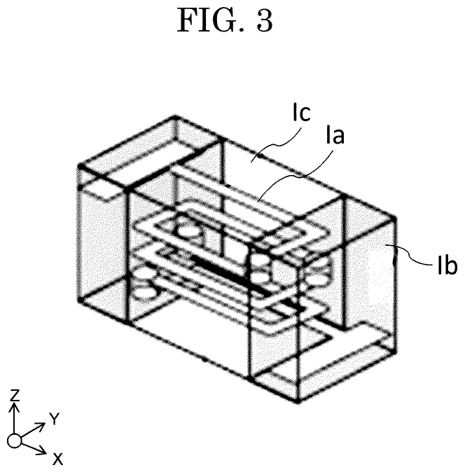

FIG. 3 is a perspective view showing a structure of a chip inductor according to the present embodiment.

The chip inductor I of the present embodiment includes a coil pattern portion ia, an external electrode portion ib, and a structure holding portion ic. The coil pattern portion ia may be a monolithic coil formed by stacking a ceramic material and a coil conductor in the Z-direction in multiple layers and connecting the respective coil conductors by vias. The coil conductor may be formed by photolithography and plating, or may be formed by printing a conductive paste. Both ends of the coil pattern portion ia are connected to the external electrode portion ib arranged to face each other across the coil pattern portion Ia. The multi-layer stacked body of an insulating material and the coil conductor is covered with the structure holding portion ic that exposes the external electrode portion Ib. The structure holding portion ic may be a non-magnetic ceramic.

The chip inductor I of the probe card 3 can be electrically connected to the inductor i of the semiconductor device C. For example, the chip inductor I of the semiconductor wafer testing apparatus is used in transmitting and receiving the signal current to and from the inductor i of the semiconductor device C.

The chip inductor I may be a cube. For example, the chip inductor I may be 100 μm square or more and 1 mm square or less. The size of the chip inductor I is preferably larger than the size of the inductor i of the semiconductor device C. The size of the chip inductor I in the X-Y direction may overlap the inductor i in a plan view. Since the chip inductor I is larger than the semiconductor device C inductor i, it is possible to manage with the positional deviation due to thermal expansion, thermal shrinkage, or the like, between the chip inductor I and the corresponding inductor i. In this case, the size of the chip inductor I indicates the largest diameter of the coil pattern portion Ia.

### Structure of Semiconductor Wafer

FIG. 4 is a top view showing a structure of a semiconductor wafer according to the present embodiment.

The semiconductor wafer W of the present embodiment includes a plurality of semiconductor devices C. The semiconductor device C is arranged in a matrix in the semiconductor wafer W. The semiconductor wafer W includes, around each semiconductor device C, an inactive element region that becomes a cutting margin when dicing the semiconductor device C. The inactive element region is arranged so as to surround the respective active element regions R1. The semiconductor wafer W is divided into the plurality of semiconductor devices C by dicing the inactive element region.

### Structure of Semiconductor Device

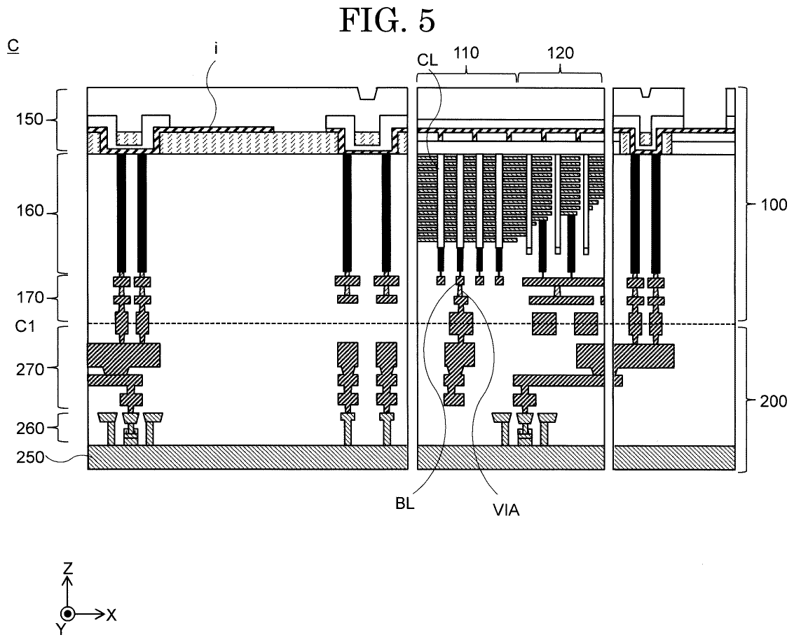

FIG. 5 is a cross-sectional view showing a structure of a semiconductor device according to the present embodiment.

The semiconductor device C of the present embodiment is a bonded wafer, and includes a memory cell array chip 100 and a control circuit (CMOS circuit) chip 200. The memory cell array chip 100 and the control circuit chip 200 are connected by a connecting surface C1.

### Structure of Memory Cell Array Chip

The memory cell array chip 100 includes a semiconductor element layer having a source line side wiring layer 150, a plurality of electrode layers 160, and a memory side wiring layer 170. The plurality of electrode layers 160 includes a memory cell array region 110 and a contact region 120. The plurality of electrode layers 160 is alternately stacked with a plurality of insulating layers (not shown). A semiconductor pillar CL is arranged through the plurality of electrode layers 160 in the stacking direction. Each of the semiconductor pillar CL functions as a plurality of transistors including a memory cell by being combined with the plurality of electrode layers 160 via an insulating layer. That is, in the memory cell array region 110, a plurality of transistors including the memory cell is three-dimensionally arranged. The semiconductor pillar CL is electrically connected at one end (the control circuit chip 200 side) to the memory side wiring layer 170 including a bit line BL, and at the other end (the control circuit chip 200 side) to the source line side wiring layer 150 including a source line. A connecting terminal for connecting to the control circuit chip 200 is arranged on the connecting surface C1 of the memory side wiring layer 170.

The contact region 120 is arranged along with the memory cell array region 110. In the contact region 120, a terminal part of each of the plurality of electrode layers 160 is led out in a stepped manner. In addition, each terminal part is connected to a wiring in the vertical direction via a contact hole opened in an insulating film. The wiring in the vertical direction is electrically connected to the memory side wiring layer 170, and is connected to the control circuit chip 200 via the connecting terminal.

### Structure of Control Circuit Chip

The control circuit chip 200 includes a semiconductor element layer including a substrate 250, a plurality of transistors 260 forming a control circuit, and a circuit side wiring layer 270. The plurality of transistors 260 is formed in the substrate 250 and is electrically connected to the circuit side wiring layer 270 opposite the substrate 250. A connecting terminal for connecting to the memory cell array chip 100 is arranged on the connecting surface C1 of the circuit side wiring layer 270. The substrate 250 may be a semiconducting wafer, such as a silicon wafer.

The semiconductor device C includes the inductor i. The inductor i may be arranged on the source line side wiring layer 150. In this case, the inductor i corresponds to a back surface wiring of the memory cell array chip 100. The inductors i may be arranged in the same layer in the Z direction. The inductor i is electrically connected to the transistor 260 of the control circuit chip 200. Part of the plurality of transistors 260 corresponds to a drive unit of the inductor i.

### Structure of Inductor

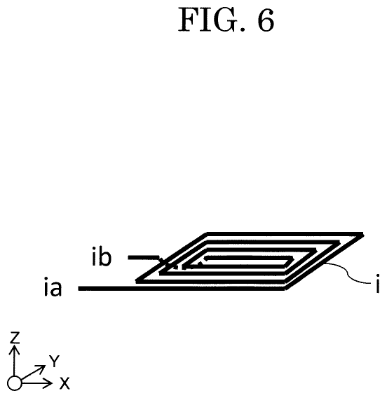

FIG. 6 is a perspective view showing a structure of an inductor according to the present embodiment.

The inductor i of the present embodiment can be electrically connected to the chip inductor I of the probe card 3. For example, the inductor i of the semiconductor device C is used in transmitting and receiving the signal current to and from the chip inductor I of the semiconductor wafer testing apparatus.

The inductor i is a coil in which the wiring layer of the semiconductor device C is spirally patterned. However, the shape of the inductor i is not particularly limited. Both ends of the inductor i are connected to the drive unit. For example, the drive unit of the inductor i may be part of the transistor 260 arranged in the control circuit chip 200. The inductor i may be square. The inductor i preferably has a size corresponding to the chip inductor I. The size of the inductor i is preferably smaller than the size of the chip inductor I. For example, the inductor i may be 50 μm square or more and 250 μm square or less. In this case, the size of the inductor i indicates the diameter in the case of a circular inductor, and the length of the longest side in the case of a rectangular inductor.

### Configuration of Semiconductor Device

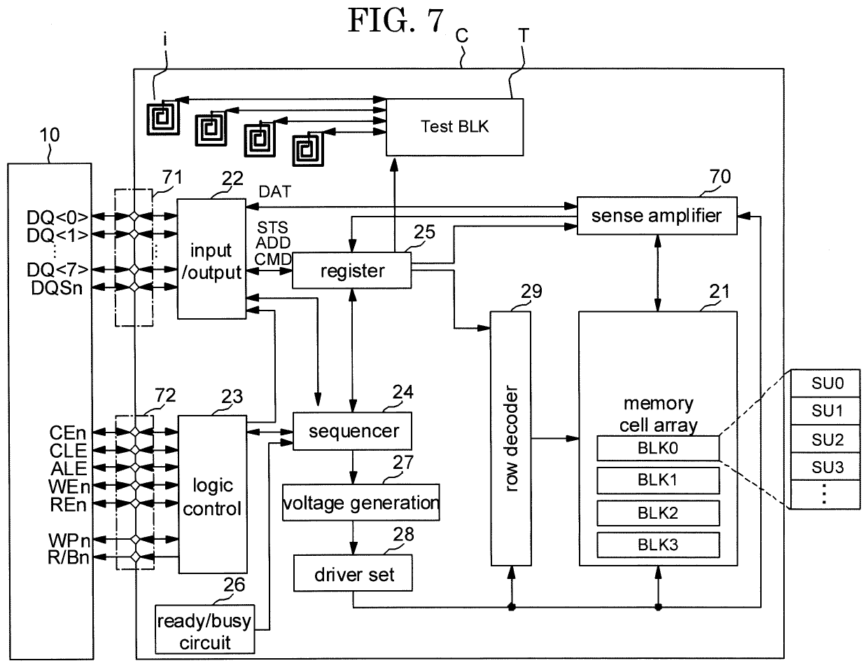

FIG. 7 is a diagram showing a configuration of a semiconductor device according to the present embodiment.

The semiconductor device C includes a memory cell array 21, an input/output circuit 22, a logic control circuit 23, a sequencer 24, a register 25, a ready/busy control circuit 26, a voltage generating circuit 27, a driver set 28, a row decoder 29, a sense amplifier module 70, an input/output pad group 71, and a logic control pad group 72. In the semiconductor device C, various operations such as a write operation for storing write data DAT in the memory cell array 21 and a read operation for reading read data DAT from the memory cell array 21 are executed.

For example, the memory cell array 21 is connected to the sense amplifier module 70, the row decoder 29, and the driver set 28. The memory cell array 21 includes blocks BLK0, BLK1, . . . , BLKn (n is an integer of 1 or more). Each of the blocks BLK includes a plurality of string units SU (SU0, SU1, SU2, SU3). Each of the string units SU includes a plurality of memory cells associated with the bit line and word line. For example, the block BLK is a data-erasing unit. The data held by the memory cells included in the same block BLK is erased collectively.

For example, the input/output circuit 22 is connected to the register 25, the logic control circuit 23, and the sense amplifier module 70. The input/output circuit 22 controls transmission and reception of a data signal DQ<7:0> between a memory interface included in a memory controller 10 and the semiconductor device C.

The signal DQ<7:0> is an entity of data transmitted and received between the semiconductor device C and the memory interface included in the memory controller 10. The signal DQ<7:0> includes a command CMD, the data DAT, an address information ADD, a status information STS, and the like.

For example, the command CMD includes a command for executing a request transmitted from a host to the semiconductor device C via the memory interface included in the memory controller 10. The data DAT includes the write data DAT to the semiconductor device C or the read data DAT from the semiconductor device C. For example, the data DAT includes Edata. For example, the address information ADD includes a column address and a row address for selecting a plurality of memory cells associated with the bit line and word line. For example, the status information STS includes information related to the status of the semiconductor device C related to the write operation and the read operation.

Specifically, the input/output circuit 22 includes an input circuit and an output circuit, and the input circuit and the output circuit perform the following processing. The memory controller 10 receives the write data DAT, the address information ADD, and the command CMD. The input circuit transmits the received write data DAT to the sense amplifier module 70, and transmits the received address information ADD and the received command CMD to the register 25. On the other hand, the output circuit receives the status information STS from the register 25 and the read data DAT from the sense amplifier module 70. The output circuit transmits the received status information STS and the read data DAT to the memory interface included in the memory controller 10.

For example, the logic control circuit 23 is connected to the memory controller 10 and the sequencer 24. For example, the logic control circuit 23 receives a chip enable signal CEn, a command latch enable signal CLE, an address latch enable signal ALE, a write enable signal WEn, a read enable signal REn, and a write protect signal WPn via the memory interface of the memory controller 10. The logic control circuit 23 controls the input/output circuit 22 and the sequencer 24 based on the received signal.

For example, the sequencer 24 is connected to the ready/busy control circuit 26, the sense amplifier module 70, and the driver set 28. The sequencer 24 controls the operation of the entire semiconductor device C based on the command CMD held in a command register. For example, the sequencer 24 controls the sense amplifier module 70, the row decoder 29, the voltage generating circuit 27, the driver set 28, and the like to execute various operations such as the write operation, the read operation, and an erase operation.

For example, the register 25 includes a status register (not shown), an address register (not shown), a command register (not shown), and the like. The status register receives and holds the status information STS from the sequencer 24, and transmits the status information STS to the input/output circuit 22 based on an instruction from the sequencer 24. The address register receives and holds the address data ADD from the input/output circuit 22. The address register transmits the column address in the address information ADD to the sense amplifier module 70, and transmits the row address in the address information ADD to the row decoder 29. The command register receives and holds the command CMD from the input/output circuit 22, and transmits the command CMD to the sequencer 24.

The ready/busy control circuit 26 generates a ready/busy signal R/Bn under the control of the sequencer 24, and transmits the generated ready/busy signal R/Bn to the memory controller 10. The ready/busy signal R/Bn is a signal for notifying whether the semiconductor device C is in a ready state for accepting an instruction from the memory controller 10 or in a busy state for not accepting an instruction.

For example, the voltage generating circuit 27 is connected to the driver set 28. The voltage generating circuit 27 generates a voltage used for the write operation, the read operation, and the like under the control of the sequencer 24, and supplies the generated voltage to the driver set 28.

The driver set 28 is connected to the memory cell array 21, the sense amplifier module 70, and the row decoder 29. For example, the driver set 28 generates various voltages or various control signals to be supplied to a select gate line SGD, a word line WL, a source line SL, a bit line BL, and the like in various operations such as the read operation and the write operation, based on the voltage supplied from the voltage generating circuit 27 or the control signal supplied from the sequencer 24. The driver set 28 supplies the generated voltage or control signal to the sense amplifier module 70, the row decoder 29, the source line SL, and the like.

The row decoder 29 receives the row address from the address register and decodes the received row address. The row decoder 29 selects the block BLK to be subjected to various operations, such as the read operation and the write operation, based on the results of the decoding. The row decoder 29 is capable of supplying a voltage supplied from the driver set 28 to the selected block BLK.

For example, the sense amplifier module 70 receives the column address from the address register, and performs the transmission/reception operation of the data DAT between the memory controller 10 and the memory cell array 21 based on the column address. In addition, the sense amplifier module 70 can sense data (threshold voltage) read from the memory cell array 21 and temporarily hold the read data (threshold voltage) based on an instruction related to the read operation. The sense amplifier module 70 can perform logical operations based on the temporarily stored data. In addition, the sense amplifier module 70 transmits the read data DAT to the memory controller 10 via the input/output circuit 22. Furthermore, the sense amplifier module 70 receives the write data DAT from the memory controller 10 via the input/output circuit 22 based on the instruction related to the write operation, and transmits the write data DAT to the memory cell array 21.

For example, the sense amplifier module 70 includes a sense amplifier unit SAU arranged for each of the bit lines BL (BL0 to BL (N−1,but (N−1) is a natural number of two or more). The sense amplifier unit SAU is electrically connected to the bit line BL so as to be able to supply a voltage. The semiconductor device C includes a memory cell transistor MT of PLC (5 bit/Cell) and has three latch circuits for storing program data (for example, EData) included in the sense amplifier unit SAU, which will be described later.

The input/output pad group 71 transmits the signal DQ<7:0> received from the memory controller 10 to the input/output circuit 22. The input/output pad group 71 transmits the signal DQ<7:0> received from the input/output circuit 22 to the memory controller 10.

The logic control pad group 72 transmits the chip enable signal CEn, the command latch enable signal CLE, the address latch enable signal ALE, the write enable signal WEn, and the read enable signal REn received from the memory controller 10 to the logic control circuit 23. The logic control pad group 72 transfers the ready/busy signal R/Bn received from the ready/busy control circuit 26 to the memory controller 10.

### Configuration of Test Block

The semiconductor device C of the present embodiment further includes a test block (Test BLK) T and the inductor i. The test block T includes a drive unit of the inductor i and is connected to the inductor i. In FIG. 7, for example, four inductors i are arranged in one semiconductor device C. However, the number of inductors i is not particularly limited, and may be three or five. The drive unit includes a signal processing circuit for processing the signal current input from the semiconductor wafer testing apparatus.

### Contactless Wireless Communication

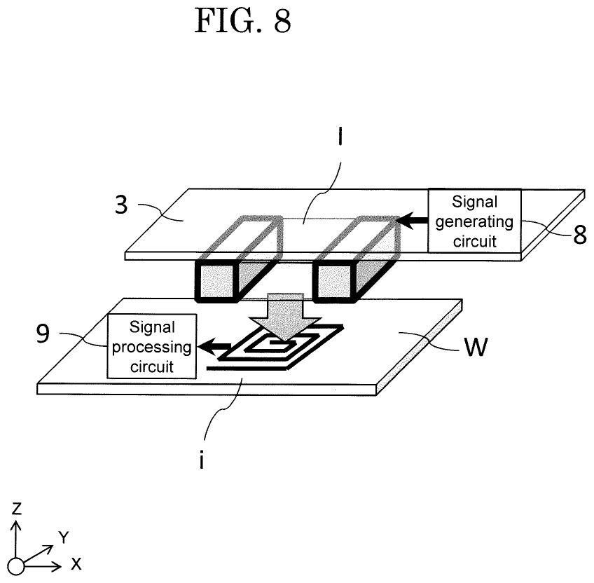

FIG. 8 is a perspective view showing a configuration of a semiconductor wafer testing apparatus and a semiconductor device and contactless wireless communication according to the present embodiment.

The probe card 3 receives the test signal from the performance board 2c and the signal current is generated by a signal generating circuit 8. The probe card 3 outputs the signal current to the chip inductor I.

The chip inductor I to which the signal current is input generates a magnetic flux, and generates an electromotive force in the inductor i of the semiconductor device C magnetically coupled to the chip inductor I by mutual induction. If the chip inductor I of the probe card 3 and the inductor i of the semiconductor device C are arranged at an appropriate interval, it is possible to transmit the signal wirelessly (non-contact). A distance between the chip inductor I of the probe card 3 and the inductor i of the semiconductor device C in the Z direction is preferably equal to or smaller than whichever is smaller, a diameter of the coil pattern portion ia of the chip inductor I or the size of the inductor i. In this case, the diameter of the coil pattern portion ia of the chip inductor I indicates the maximum diameter of the coil pattern portion ia, the size of the inductor i indicates the diameter in the case of a circular inductor, and the length of the maximum side in the case of a rectangular inductor. For example, the distance between the chip inductor I of the probe card 3 and the inductor i of the semiconductor device C in the Z direction is preferably 100 μm or less. The signal current generated in the inductor i of the semiconductor device C is transmitted to the test block T and processed into the test signal by a signal processing circuit 9.

The test block T tests the operation of the entire semiconductor device C based on the test signal. For example, the test block T receives a signal from the register 25 and controls the sense amplifier module 70, the row decoder 29, the voltage generating circuit 27, the driver set 28, and the like to perform a test for whether various operations such as the write operation, the read operation, and the erase operation are normally performed.

In the present embodiment, an independent test block T is arranged in the semiconductor device C. However, the present invention is not limited to this, and for example, the test block T may be arranged as a part of the logic control circuit 23 or the sequencer 24. In this case, the inductor i may be connected to the logic control circuit 23 or the sequencer 24.

The semiconductor wafer testing apparatus according to the present embodiment can reduce the cost of replacing components due to the wear of the contact portion that exists when the conventional means is used by transmitting the test signal using the semiconductor device C of the semiconductor wafer W and the contactless communication means, can reduce the loads on the movable portion of the semiconductor wafer testing apparatus, and can reduce failures or a failure rate of a communication device. In addition, the semiconductor wafer testing apparatus uses magnetic coupling to make it easier to use a high-speed signal and to shorten the measuring time. Using the chip inductor I in the semiconductor wafer testing apparatus makes it possible to obtain an inexpensive and stable measuring system.

### Second Embodiment

### Contactless Wireless Communication

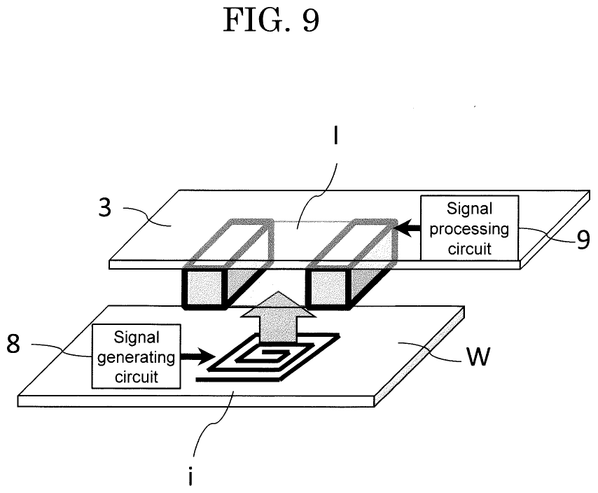

The configuration of the semiconductor wafer testing apparatus and the semiconductor device and the contactless wireless communication according to the present embodiment will be described with reference to FIG. 9. FIG. 9 is a perspective view showing the configuration of the semiconductor wafer testing apparatus and the semiconductor device and the contactless wireless communication according to the present embodiment. The semiconductor device C according to the present embodiment includes the signal generating circuit 8, and the probe card 3 includes the signal processing circuit 9, and is the same as the configuration of the first embodiment except that the signal is transmitted in the opposite direction. Descriptions that are the same as those of the first embodiment will be omitted, and portions different from those of the first embodiment will be described here.

The semiconductor wafer W includes the signal generating circuit 8 for generating the signal current to be input to the probe card 3, and the probe card 3 includes the signal processing circuit 9 for processing the signal current to be output from the semiconductor wafer W.

The test block T of the semiconductor device C tests the operation of the entire semiconductor device C. For example, the test block T receives the signal from the register 25 and controls the sense amplifier module 70, the row decoder 29, the voltage generating circuit 27, the driver set 28, and the like to perform a test for whether various operations such as the write operation, the read operation, and the erase operation are normally performed. The test block T generates the test signal that has tested the semiconductor wafer W. The test block T of the semiconductor device C generates the signal current from the test signal generated by the signal generating circuit 8. The test block T outputs the signal current to the inductor i.

The inductor i to which the signal current is input generates a magnetic flux, and generates an electromotive force in the chip inductor I of the probe card 3 magnetically coupled to the inductor i by mutual induction. If the semiconductor device C inductor i and the chip inductor I of the probe card 3 are arranged at an appropriate interval, it is possible to transmit the signal wirelessly (non-contact). A distance between the semiconductor device C inductor i and the chip inductor I of the probe card 3 in the Z direction is preferably equal to or smaller than whichever is smaller, the diameter of the coil pattern portion ia of the chip inductor I or the size of the inductor i. For example, the distance between the chip inductor I of the probe card 3 and the inductor i of the semiconductor device C in the Z direction is preferably 100 um or less. The signal current generated in the chip inductor I of the probe card 3 is transmitted to the probe card 3 and processed into the test signal by the signal processing circuit 9.

The probe card 3 outputs the test signal to the performance board 2c. The performance board 2c receives the test signal from the probe card 3 and outputs the test signal to the test head 2b. The test head 2b receives the test signal from the performance board 2c and outputs the test signal to the tester body 2a via the cable C.

The semiconductor wafer testing apparatus according to the present embodiment can reduce the cost of replacing components due to the wear of the contact portion that exists when the conventional means is used by transmitting the test signal using the semiconductor device C of the semiconductor wafer W and the contactless communication means, can reduce the loads on the movable portion of the semiconductor wafer testing apparatus, and can reduce failures or a failure rate of a communication device. In addition, the semiconductor wafer testing apparatus uses magnetic coupling to make it easier to use a high-speed signal and to shorten the measuring time. Using the chip inductor I in the semiconductor wafer testing apparatus makes it possible to obtain an inexpensive and stable measuring system.

### Third Embodiment

### Contactless Wireless Communication

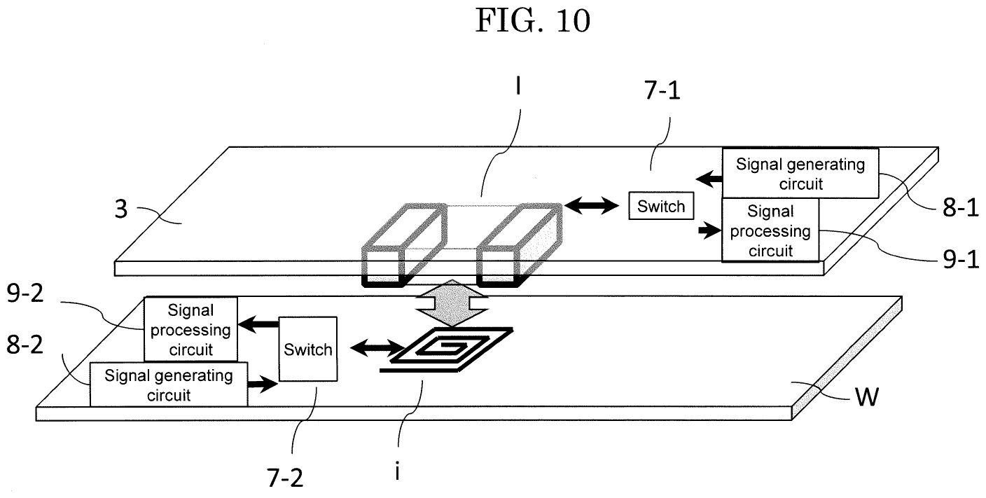

The configuration of the semiconductor wafer testing apparatus and the semiconductor device and the contactless wireless communication according to the present embodiment will be described with reference to FIG. 10. FIG. 10 is a perspective view showing the configuration of the semiconductor wafer testing apparatus and the semiconductor device and the contactless wireless communication according to the present embodiment. The probe card 3 according to the present embodiment includes a signal generating circuit 8-1 and a signal processing circuit 9-1, and the semiconductor device C includes a signal generating circuit 8-2 and a signal processing circuit 9-2, and is the same as the configurations of the first and second embodiments except that the signal can be transmitted in both directions. Descriptions that are the same as those of the first embodiment and the second embodiment are omitted, and portions different from those of the first embodiment and the second embodiment will be described here.

The probe card 3 of the present embodiment includes the signal generating circuit 8-1 for generating a signal current to be input to the semiconductor wafer W and the signal processing circuit 9-1 for processing the signal current to be output from the semiconductor wafer W, and the semiconductor wafer W includes the signal generating circuit 8-2 for generating a signal current to be input to the probe card 3 and the signal processing circuit 9-2 for processing the signal current to be output from the probe card 3 (they are referred to as the signal processing circuit 9 when the signal processing circuit 9-1 and the signal processing circuit 9-2 are not distinguished from each other). The probe card 3 further includes a switch 7-1 for switching the signal generating circuit 8-1 and the signal processing circuit 9-1, and the semiconductor wafer W further includes a switch 7-2 for switching the signal generating circuit 8-2 and the signal processing circuit 9-2 (they are referred to as the switch 7 when the switch 7-1 and the switch 7-2 are not distinguished from each other).

When the probe card 3 generates the signal current to be input to the semiconductor wafer W by the signal generating circuit 8-1, the switch 7-1 is connected to the signal generating circuit 8-1 and shuts off the signal processing circuit 9-1. In this case, the semiconductor wafer W processes the signal current output from the probe card 3 by the signal processing circuit 9-2, and the switch 7-2 is connected to the signal processing circuit 9-2 to shut off the signal generating circuit 8-2. With this configuration, it is possible to suppress the signal current from flowing from each signal generating circuit 8 to the signal processing circuit 9, and to perform the same contactless wireless communication as the contactless wireless communication between the semiconductor wafer testing apparatus and the semiconductor device according to the first embodiment.

When the semiconductor wafer W generates the signal current to be input to the probe card 3 by the signal generating circuit 8-2, the switch 7-2 is connected to the signal generating circuit 8-2 and shuts off the signal processing circuit 9-2. In this case, the probe card 3 processes the signal current output from the semiconductor wafer W by the signal processing circuit 9-1, and the switch 7-1 is connected to the signal processing circuit 9-1 to shut off the signal generating circuit 8-1. With this configuration, it is possible to suppress the signal current from flowing from each signal generating circuit 8 to the signal processing circuit 9, and to perform the same contactless wireless communication as the contactless wireless communication between the semiconductor wafer testing apparatus and the semiconductor device according to the second embodiment.

The semiconductor wafer testing apparatus according to the present embodiment can transmit the test signal by using the contactless communication means in both directions with the semiconductor device C of the semiconductor wafer W.

### Fourth Embodiment

### Contactless Wireless Communication

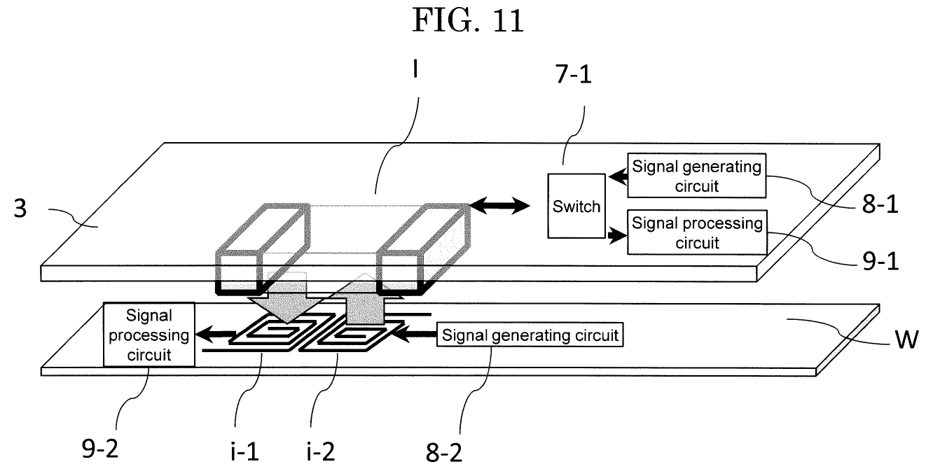

The configuration of the semiconductor wafer testing apparatus and the semiconductor device and the contactless wireless communication according to the present embodiment will be described with reference to FIG. 11. FIG. 11 is a perspective view showing the configuration of the semiconductor wafer testing apparatus and the semiconductor device and the contactless wireless communication according to the present embodiment. The semiconductor device C includes an inductor i-2 connected to the signal generating circuit 8-2 and an inductor i-1 connected to the signal processing circuit 9-2, and is the same as the configuration of the third embodiment except that the signal can be transmitted in both directions. Descriptions that are the same as those of the first to third embodiments are omitted, and portions different from those of the first to third embodiments will be described here.

The probe card 3 of the present embodiment includes the signal generating circuit 8-1 for generating the signal current to be input to the semiconductor wafer W and the signal processing circuit 9-1 for processing the signal current to be output from the semiconductor wafer W, and the semiconductor wafer W includes the signal generating circuit 8-2 for generating the signal current to be input to the probe card 3 and the signal processing circuit 9-2 for processing the signal current to be output from the probe card 3. The probe card 3 further includes the switch 7-1 for switching between the signal generating circuit 8-1 and the signal processing circuit 9-1, and the semiconductor wafer W further includes the inductor i-2 connected to the signal generating circuit 8-2 and the inductor i-1 connected to the signal processing circuit 9-2. One chip inductor I of the present embodiment is arranged for two inductors i. However, the number of inductors i is not limited to this, and one chip inductor I may be arranged for the plurality of inductors i.

The size of the chip inductor I of the present embodiment is a size including a region through which the magnetic flux of both an inductor ia and an inductor ib passes. The size of the chip inductor I in the X-Y direction may overlap both the inductor ia and the inductor ib in a plan view. The size of the chip inductor I in the X-Y direction may be twice the size of the inductor i.

When the probe card 3 generates the signal current to be input to the semiconductor wafer W by the signal generating circuit 8-1, the switch 7-1 is connected to the signal generating circuit 8-1 and shuts off the signal processing circuit 9-1. The chip inductor I of the probe card 3 transmits the signal to the inductor i-1 of the semiconductor device C wirelessly (non-contact). The semiconductor wafer W transmits the signal current to the signal processing circuit 9-2 by the inductor i-1, and processes the signal current output from the probe card 3. With this configuration, it is possible to suppress the signal current from flowing from the signal generating circuit 8-1 to the signal processing circuit 9-1, and to perform the same contactless wireless communication as the contactless wireless communication between the semiconductor wafer testing apparatus and the semiconductor device according to the first embodiment.

When the semiconductor wafer W generates the signal current to be input to the probe card 3 by the signal generating circuit 8-2, the inductor i-2 of the semiconductor device C transmits the signal to the chip inductor I of the probe card 3 wirelessly (non-contact). The probe card 3 processes the signal current output from the semiconductor wafer W by the signal processing circuit 9-1, and the switch 7-1 is connected to the signal processing circuit 9-1 to shut off the signal generating circuit 8-1. With such a configuration, it is possible to suppress the signal current from flowing from the signal processing circuit 9-1 to the signal generating circuit 8-1, and to perform the same contactless wireless communication as the contactless wireless communication between the semiconductor wafer testing apparatus and the semiconductor device according to the second embodiment.

The semiconductor wafer testing apparatus according to the present embodiment can transmit the test signal by using the contactless communication means in both directions with the semiconductor device C of the semiconductor wafer W. Since the semiconductor device C includes the inductor i-2 connected to the signal generating circuit 8-2 and the inductor i-1 connected to the signal processing circuit 9-2, the voltage controllability is further improved.

### Fifth Embodiment

### Contactless Wireless Communication

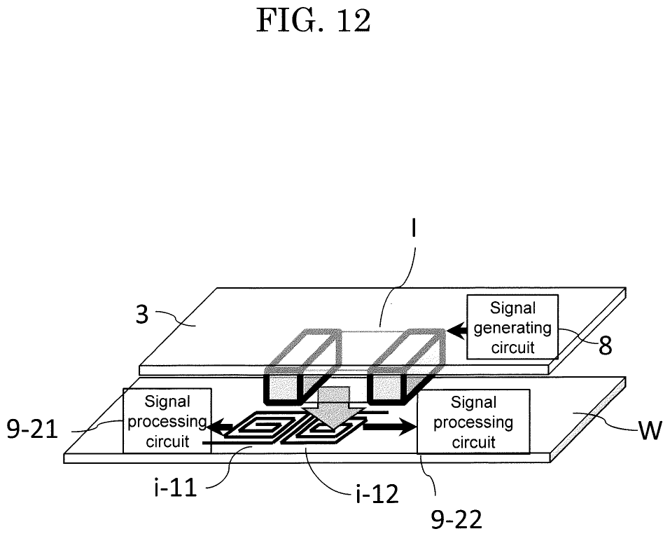

The configuration of the semiconductor wafer testing apparatus and the semiconductor device and the contactless wireless communication according to the present embodiment will be described with reference to FIG. 12. FIG. 12 is a perspective view showing the configuration of the semiconductor wafer testing apparatus and the semiconductor device and the contactless wireless communication according to the present embodiment. The semiconductor device C is the same as that of the first embodiment except that it includes an inductor i-11 connected to a signal processing circuit 9-21 and an inductor i-12 connected to a signal processing circuit 9-22. Descriptions that are the same as those of the first embodiment will be omitted, and portions different from those of the first embodiment will be described here.

The probe card 3 of the present embodiment includes the signal generating circuit 8 for generating the signal current to be input to the semiconductor wafer W, and the semiconductor wafer W includes the signal processing circuit 9-21 and the signal processing circuit 9-22 for processing the signal current output from the probe card 3 (they are referred to as the signal processing circuit 9 when the signal processing circuit 9-21 and the signal processing circuit 9-22 are not distinguished from each other).

When the probe card 3 generates the signal current to be input to the semiconductor wafer W by the signal generating circuit 8, the chip inductor I of the probe card 3 transmits the signal wirelessly (non-contact) to the inductor i-11 or the inductor i-12 of the semiconductor device C. The semiconductor wafer W transmits the signal current to the signal processing circuit 9-21 or the signal processing circuit 9-22 by the inductor i-11 or the inductor i-12, and processes the signal current output from the probe card 3. With this configuration, it is possible to perform the same contactless wireless communication as the contactless wireless communication between the semiconductor wafer testing apparatus and the semiconductor device according to the first embodiment.

In the semiconductor wafer testing apparatus according to the present embodiment, since the semiconductor device C includes the inductor i-11 and the inductor i-12, it is possible to manage the positional deviation due to thermal expansion, thermal shrinkage, or the like, further improving the contactless wireless communication with the semiconductor device C.

In addition, two signal processing circuits 9 and two inductors i are arranged in the semiconductor device C in the present embodiment. However, the present invention is not limited to this, and two signal generating circuits 8 and two inductors i are arranged in the semiconductor device C in the configuration of the second embodiment, so that the contactless wireless communication in the opposite direction can be further improved. In addition, two inductors i are arranged in the semiconductor device C and connected to one switch 7-2 in the configuration of the third embodiment, whereby the contactless wireless communication in both directions can be further improved.

### Sixth Embodiment

### Contactless Wireless Communication

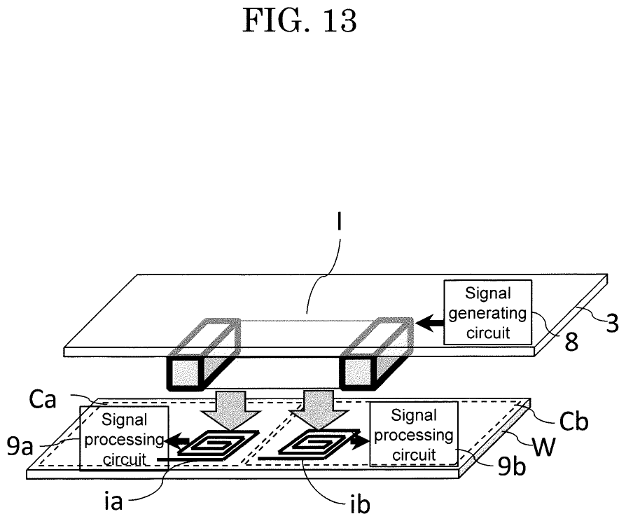

The configuration of the semiconductor wafer testing apparatus and the semiconductor device and the contactless wireless communication according to the present embodiment will be described with reference to FIG. 13. FIG. 13 is a perspective view showing the configuration of the semiconductor wafer testing apparatus and the semiconductor device and the contactless wireless communication according to the present embodiment. The configuration of the chip inductor I is the same as that of the first embodiment except that the chip inductor I is magnetically coupled to the inductors i of two semiconductor devices C. Descriptions that are the same as those of the first embodiment will be omitted, and portions different from those of the first embodiment will be described here.

The probe card 3 of the present embodiment includes the signal generating circuit 8 for generating the signal current to be input to the semiconductor wafer W. The semiconductor wafer W includes the semiconductor device Ca and the semiconductor device Cb (they are referred to as the semiconductor device C when the semiconductor device Ca and the semiconductor device Cb are not distinguished from each other). The semiconductor device Ca includes the inductor ia and a signal processing circuit 9a for processing the signal current output from the probe card 3. The semiconductor device Cb includes the inductor ib and a signal processing circuit 9b for processing the signal current output from the probe card 3 (they are referred to as the signal processing circuit 9 when the signal processing circuit 9a and the signal processing circuit 9b are not distinguished from each other, and they are referred to as the inductor i when the inductor ia and the inductor ib are not distinguished from each other). One chip inductor I of the present embodiment is arranged for two inductors i. However, the number of inductors i is not limited to this, and one chip inductor I is arranged for the plurality of inductors i.

The size of the chip inductor I of the present embodiment is a size including a region through which the magnetic flux of both the inductor ia and the inductor ib passes. The size of the chip inductor I in the X-Y direction may overlap both the inductor ia and the inductor ib in a plan view. The size of the chip inductor I in the X-Y direction may be twice the size of the inductor i.

When the probe card 3 generates the signal current to be input to the semiconductor wafer W by the signal generating circuit 8, the chip inductor I of the probe card 3 transmits the signal wirelessly (non-contact) to an inductor i-1a of the semiconductor device Ca and the inductor ib of the semiconductor device Cb. The semiconductor device Ca transmits the signal current to the signal processing circuit 9a by the inductor ia, and processes the signal current output from the probe card 3. The semiconductor device Cb transmits the signal current to the signal processing circuit 9b by the inductor ib, and processes the signal current output from the probe card 3. With this configuration, it is possible to perform the same contactless wireless communication as the contactless wireless communication between the semiconductor wafer testing apparatus and the semiconductor device according to the first embodiment.

In the semiconductor wafer testing apparatus according to the present embodiment, since one chip inductor I is magnetically coupled to the inductors i of two semiconductor devices C, the number of chip inductors I included in the probe card 3 can be suppressed, and the contactless wireless communication can be further improved.

In addition, the signal processing circuit 9 and the inductor i are respectively arranged in two semiconductor devices C in the present embodiment. However, the present invention is not limited to this, and in the configuration of the second embodiment, the signal generating circuit 8 and the inductor i are arranged in two semiconductor devices C, respectively, further improving the contactless wireless communication in the opposite direction. In addition, in the configuration of the third embodiment, the switch 7, the signal generating circuit 8, the signal processing circuit 9, and the inductor i are arranged in two semiconductor devices C, respectively, further improving the contactless wireless communication in both directions.

### Seventh Embodiment

### Contactless Wireless Communication

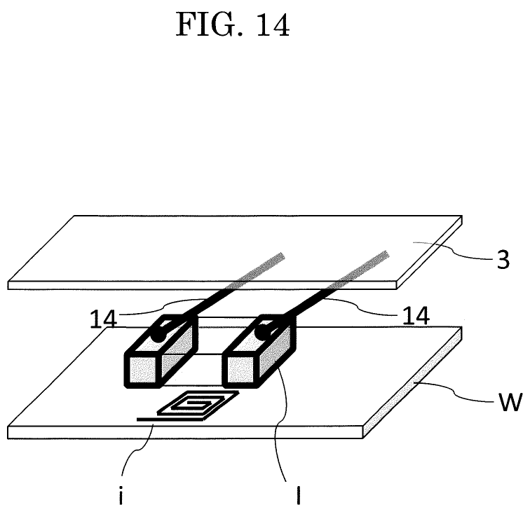

The configuration of the semiconductor wafer testing apparatus and the semiconductor device and the contactless wireless communication according to the present embodiment will be described with reference to FIG. 14. FIG. 14 is a perspective view showing the configuration of the semiconductor wafer testing apparatus and the semiconductor device and the contactless wireless communication according to the present embodiment. The chip inductor I is the same as the configuration of the first to sixth embodiments except that it is connected to a circuit of the probe card 3 via two conductive wires 14. Descriptions that are the same as those of the first to sixth embodiments are omitted, and portions different from those of the first to sixth embodiments will be described here.

The two external electrode portions Ib of the chip inductor I of the present embodiment are connected to the signal generating circuit 8, the signal processing circuit 9, or the signal generating circuit 8 and the signal processing circuit 9 of the probe card 3 via the conductive wires 14, respectively. The chip inductor I is supported by the probe card 3 by the conductive wire 14 and held in position. The conductive wire 14 may be rigid. The conductive wire 14 may have a spring property.

Since the semiconductor wafer testing apparatus according to the present embodiment is supported by the probe card 3 by the conductive wire 14, the position of the chip inductor I can be easily adjusted, and a distance between the chip inductor I and the inductor i can be easily reduced. In addition, the chip inductor I can be arranged in contact with the semiconductor device C. In this case, the distance between the probe card 3 and the inductor i can be adjusted in accordance with or automatically adjusted within an elastic range of the spring property of the conductive wire 14.

### Eighth Embodiment

### Contactless Wireless Communication

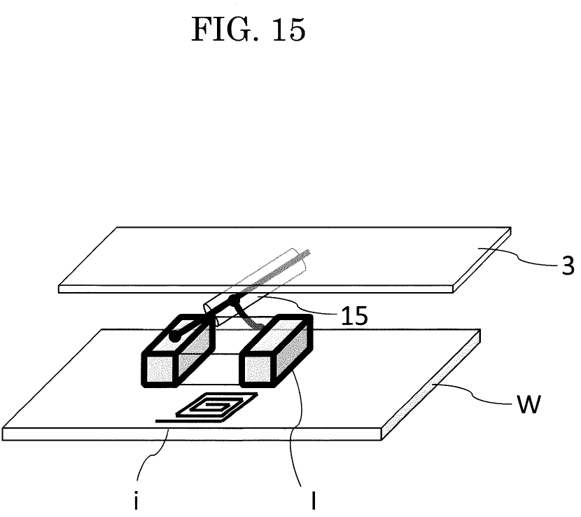

The configuration of the semiconductor wafer testing apparatus and the semiconductor device and the contactless wireless communication according to the present embodiment will be described with reference to FIG. 15. FIG. 15 is a perspective view showing the configuration of the semiconductor wafer testing apparatus and the semiconductor device and the contactless wireless communication according to the present embodiment. The chip inductor I is the same as the configuration of the first to sixth embodiments except that it is connected to the circuit of the probe card 3 via one coaxial cable 15. Descriptions that are the same as those of the first to sixth embodiments are omitted, and portions different from those of the first to sixth embodiments will be described here.

The chip inductor I of the present embodiment is connected to the signal generating circuit 8, the signal processing circuit 9, or the signal generating circuit 8 and the signal processing circuit 9 of the probe card 3 via one coaxial cable 15. One external electrode portion ib of the chip inductor I is connected to the center conductor of the coaxial cable 15, and one external electrode portion ib of the chip inductor I is connected to the external conductor of the coaxial cable 15. The chip inductor I is supported by the probe card 3 by the coaxial cable 15 and held in position.

The semiconductor wafer testing apparatus according to the present embodiment can reduce noise entering the wiring connected to one of the external electrode portions Ib of the chip inductor I.

### Ninth Embodiment

### Contactless Wireless Communication

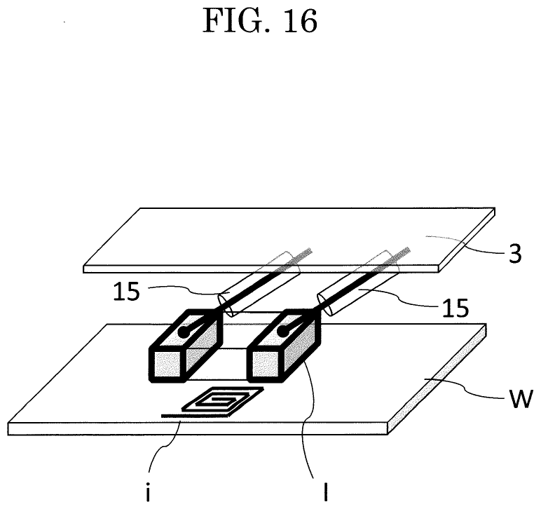

The configuration of the semiconductor wafer testing apparatus and the semiconductor device and the contactless wireless communication according to the present embodiment will be described with reference to FIG. 16. FIG. 16 is a perspective view showing the configuration of the semiconductor wafer testing apparatus and the semiconductor device and the contactless wireless communication according to the present embodiment. The chip inductor I is the same as the configuration of the first to sixth embodiments except that it is connected to the circuit of the probe card 3 via two coaxial cables 15. Descriptions that are the same as those of the first to sixth embodiments are omitted, and portions different from those of the first to sixth embodiments will be described here.

The chip inductor I of the present embodiment is connected to the signal generating circuit 8, the signal processing circuit 9, or the signal generating circuit 8 and the signal processing circuit 9 of the probe card 3 via two coaxial cables 15. The two external electrode portions ib of the chip inductor I are connected to the center conductor of the coaxial cable 15, respectively. The chip inductor I is supported by the probe card 3 by the coaxial cable 15 and held in position.

The semiconductor wafer testing apparatus according to the present embodiment can reduce noise entering the wiring connected to both external electrode portions Ib of the chip inductor I.

### Tenth Embodiment

### Contactless Wireless Communication

The configuration of the semiconductor wafer testing apparatus and the semiconductor device and the contactless wireless communication according to the present embodiment will be described with reference to FIG. 17. FIG. 17 is a perspective view showing the configuration of the semiconductor wafer testing apparatus and the semiconductor device and the contactless wireless communication according to the present embodiment. The chip inductor I is the same as the configuration of the first to sixth embodiments except that it is connected to the circuit of the probe card 3 via one two-core coaxial cable 17. Descriptions that are the same as those of the first to sixth embodiments are omitted, and portions different from those of the first to sixth embodiments will be described here.

The chip inductor I of the present embodiment is connected to the signal generating circuit 8, the signal processing circuit 9, or the signal generating circuit 8 and the signal processing circuit 9 of the probe card 3 via one two-core coaxial cable 17. The two external electrode portions ib of the chip inductor I are connected to the center conductor of the two-core coaxial cable 17, respectively. The chip inductor I is supported by the probe card 3 by the coaxial cable 15 and held in position.

The semiconductor wafer testing apparatus according to the present embodiment can reduce noise entering the wiring connected to both the external electrode portions Ib of the chip inductor I.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor wafer testing apparatus comprising:
a stage configured to place a semiconductor wafer having a plurality of first coils;
a probe card configured to hold a plurality of chip inductors having a plurality of second coils;
a driver configured to move the probe card toward the stage; and
a control circuit including a plurality of transmitting circuits or a plurality of receiving circuits connected to each of the plurality of chip inductors;
wherein the control circuit is configured to transmit signals to the plurality of first coils by magnetically coupling the plurality of first coils to each of the plurality of second coils.

2. The semiconductor wafer testing apparatus according to claim 1, wherein the plurality of chip inductors is spaced apart from each other.

3. The semiconductor wafer testing apparatus according to claim 1, wherein a size of the plurality of second coils of the plurality of chip inductors is larger than a size of the plurality of first coils of the semiconductor wafer.

4. The semiconductor wafer testing apparatus according to claim 1, wherein a size of the plurality of second coils of the plurality of chip inductors is twice as large as a size of the plurality of first coils of the semiconductor wafer.

5. The semiconductor wafer testing apparatus according to claim 1, wherein the plurality of chip inductors is each held by the probe card via two rigid conductive wires.

6. The semiconductor wafer testing apparatus according to claim 1, wherein the plurality of chip inductors is each held by the probe card via a coaxial cable.

7. The semiconductor wafer testing apparatus according to claim 1, wherein the plurality of chip inductors is each held by the probe card via two coaxial cables.

8. The semiconductor wafer testing apparatus according to claim 1, wherein the plurality of chip inductors is each held by the probe card via a two-core coaxial cable.

9. The semiconductor wafer testing apparatus according to claim 1, wherein the control circuit includes the plurality of transmitting circuits and the plurality of receiving circuits connected to each of the plurality of chip inductors, and a switch circuit arranged between the transmitting circuit and the receiving circuit.

10. The semiconductor wafer testing apparatus according to claim 4, wherein each of the plurality of chip inductors is configured to be magnetically coupled to two of the plurality of first coils, so that the control circuit transmits signals to the two first coils.

11. The semiconductor wafer testing apparatus according to claim 10, wherein the semiconductor wafer includes a plurality of semiconductor devices, and the two first coils are arranged in different semiconductor devices.
